(19) United States
(12) Patent Application Publication
(10) Pub. No.: US 2025/0127013 A1
(43) Pub. Date: Apr. 17, 2025

(54) DISPLAY DEVICE AND METHOD OF MANUFACTURING THE SAME

(71) Applicant: Samsung Display Co., LTD., Yongin-si (KR)

(72) Inventor: GEUN-HO LEE, Yongin-si (KR)

(21) Appl. No.: 18/904,645

(22) Filed: Oct. 2, 2024

(30) Foreign Application Priority Data
Oct. 11, 2023 (KR) 10-2023-0135483

(51) Int. Cl. H10K 59/80; H05K 5/02; H05K 5/03; H10K 59/12

(52) U.S. Cl. CPC H10K 59/872; H05K 5/0217; H05K 5/03; H10K 59/1201

(57) ABSTRACT

A display device includes: a display panel; a cover under the display panel; a set bracket accommodating the cover and including a bottom part and a side part connected to the bottom part, wherein the side part of the set bracket defines a groove; and a flange including: a first part accommodated by the groove; a second part contacting the first part; and a third part including a contact surface contacting the cover and a first corner portion contacting the contact surface, wherein the first corner portion has a chamfered shape in a cross-sectional view.

### CROSS-REFERENCE TO RELATED APPLICATION

The present application claims priority to and benefits of Korean Patent Application No. 10-2023-0135483, filed on Oct. 11, 2023, in the Korean Intellectual Property Office, the entire disclosure of which is incorporated herein by reference.

### BACKGROUND

### 1. Technical

Aspects of some embodiments of the present disclosure relate to a display device and a method of manufacturing the same.

### 2. Description of the Related Art

A display device is a device that displays images for providing visual information to users. Among display devices, an organic light emitting diode display has recently attracted attention.

The display device may include a display panel, a set bracket, and a flange. The set bracket may be combined under the display panel. The flange may support and guide the display panel when the display panel and the set bracket are combined.

The above information disclosed in this Background section is only for enhancement of understanding of the background and therefore the information discussed in this Background section does not necessarily constitute prior art.

### SUMMARY

Aspects of some embodiments of the present disclosure relate to a display device and a method of manufacturing the same. For example, aspects of some embodiments of the present disclosure relate to a display device including a flange.

Aspects of some embodiments include a display device with improved quality.

Aspects of some embodiments include a method of manufacturing the display device.

A display device according to some embodiments includes a display panel, a cover under the display panel, a set bracket accommodating the cover and including a bottom part and a side part connected to the bottom part, and a flange.

According to some embodiments, the side part of the set bracket may define a groove.

According to some embodiments, the flange includes a first part accommodated by the groove, a second part in contact with the first part, and a third part including a contact surface in contact with the cover and a first corner portion in contact with the contact surface.

According to some embodiments, the first corner portion may have a chamfered shape in a cross-sectional view.

According to some embodiments, the first part of the flange may have a convex shape in a direction away from the second part of the flange.

According to some embodiments, the first part of the flange may be spaced apart from the side part of the set bracket.

According to some embodiments, the first corner portion of the third part of the flange may be spaced apart from the cover.

According to some embodiments, the first corner portion of the third part of the flange may have a convex shape toward the cover.

According to some embodiments, the flange may further include a fourth part connecting the second part of the flange and the third part of the flange.

According to some embodiments, the fourth part may be parallel to the side part of the set bracket.

According to some embodiments, the first part of the flange may include a parallel plane which is parallel to the side part of the set bracket and a second corner portion adjacent to the parallel plane.

According to some embodiments, the second corner portion of the first part of the flange may have a chamfered shape in a cross-sectional view.

According to some embodiments, the second corner portion of the first part of the flange may have a convex shape in a direction way from the second part of the flange.

According to some embodiments, the set bracket may further include a supporting part in contact with each of the bottom part of the set bracket and the side part of the set bracket.

According to some embodiments, the cover may be attached to the supporting part by tape.

According to some embodiments, the side part of the set bracket may be connected to an edge of the bottom part of the set bracket.

According to some embodiments, the flange may include metal.

A method of manufacturing a display device according to some embodiments includes forming a display panel, forming a cover under the display panel, forming a flange including a first part, a second part in contact with the first part, and a third part including a contact surface in contact with the cover and a first corner portion in contact with the contact surface, forming a set bracket accommodating the cover and including a bottom part and a side part connected to the bottom part, aligning the display panel, the cover, the flange, and the set bracket so that the first part of the flange is accommodated by the groove of the side part of the set bracket, and rotating the display panel, the cover, and the flange so that the cover is attached to the set bracket.

According to some embodiments, the first corner portion may have a chamfered shape in a cross-sectional view;

According to some embodiments, the side part of the set bracket may define a groove;

According to some embodiments, the first part of the flange may have a convex shape in a direction away from the second part of the flange.

According to some embodiments, the groove of the side part of the set bracket may extend in one direction.

According to some embodiments, the rotating the display panel, the cover, and the flange may include rotating the display panel, the cover, and the flange with the one direction as an axis.

According to some embodiments, the first part of the flange may be spaced apart from the side part of the set bracket.

According to some embodiments, the first corner portion of the third part of the flange may be spaced apart from the cover.

According to some embodiments, the first corner portion of the third part of the flange may have a convex shape toward the cover.

A display device according to some embodiments may include a display panel, a cover under the display panel, a set bracket accommodating the cover, and a flange. According to some embodiments, the set bracket may include a bottom part and a side part connected to the bottom part and defining a groove. According to some embodiments, the flange may include a first part accommodated by the groove of the side part of the set bracket, a second part in contact with the first part, and a third part including a contact surface in contact with the cover and a first corner portion in contact with the contact surface. According to some embodiments, the first corner portion has a chamfered shape in a cross-sectional view.

Accordingly, when the first part of the flange rotates, the first part of the flange may not be in contact with the side part of the set bracket. Thus, an impact may not occur between the first part of the flange and the side part of the set bracket. Thus, transfer of an impact from the first part of the flange to the display panel and the cover through the flange may be prevented or reduced.

### BRIEF DESCRIPTION OF DRAWINGS

Illustrative, non-limiting embodiments will be more clearly understood from the following detailed description in conjunction with the accompanying drawings.

FIG. 1 is a plan view illustrating a display device according to some embodiments.

FIG. 2 is a cross-sectional view of the display device of FIG. 1 taken along the line I-I′.

FIG. 3 is an enlarged cross-sectional view of a flange included in the display device of FIG. 2.

FIG. 4 is a plan view illustrating an XY portion of the display device of FIG. 2.

FIG. 5 is a cross-sectional view illustrating a pixel included in the display device of FIG. 1.

FIGS. 6, 7, and 8 are cross-sectional views illustrating a method of manufacturing the display device of FIG. 2.

FIG. 9 is a cross-sectional view illustrating a flange according to some embodiments.

### DETAILED DESCRIPTION

Hereinafter, display devices in accordance with some embodiments will be described in more detail with reference to the accompanying drawings. The same reference numerals are used for the same components in the drawings, and some redundant descriptions of the same components may be omitted.

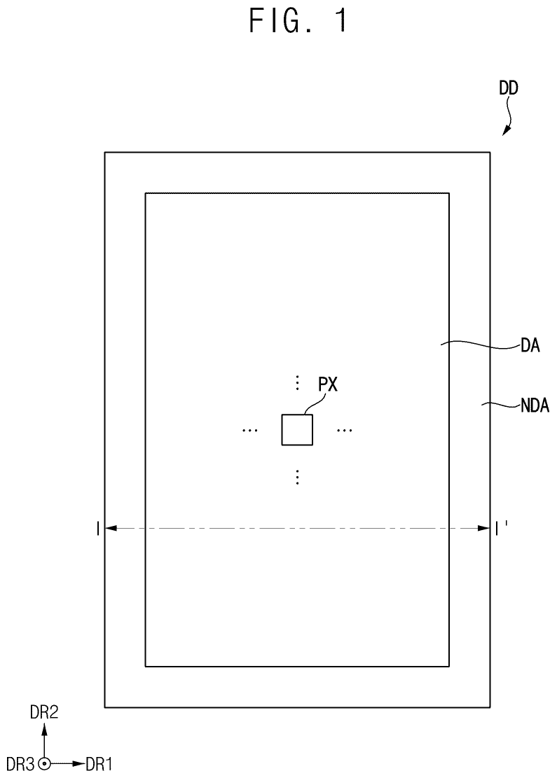

FIG. 1 is a plan view illustrating a display device according to some embodiments.

Referring to FIG. 1, a display device DD according to some embodiments may include a display area DA and a non-display area NDA. The display area DA may be defined as an area capable of emitting light. In addition, components for transmitting signals to the display area DA may be located in the non-display area NDA.

A plurality of pixels may be located in the display area DA. For example, a pixel PX may be located in the display area DA. Each of the plurality of pixels may refer to an area in which light emitted from a light emitting element is emitted to outside of the display device DD. For example, the pixel PX may refer to an area in which light emitted from a light emitting element (for example, a light emitting element LED of FIG. 7) is emitted to the outside of the display device DD. The plurality of pixels may be repeatedly arranged in a first direction DR1 and a second direction DR2 crossing the first direction DR1.

The non-display area NDA may be arranged around (e.g., in a periphery or outside a footprint of) the display area DA. For example, the non-display area NDA may surround at least a portion of the display area DA. A driving unit may be located in the non-display area NDA. The driving unit may provide a signal or a voltage to the plurality of pixels. For example, the driving unit may include a data driving unit, a gate driving unit, and the like. The non-display area NDA may not display an image.

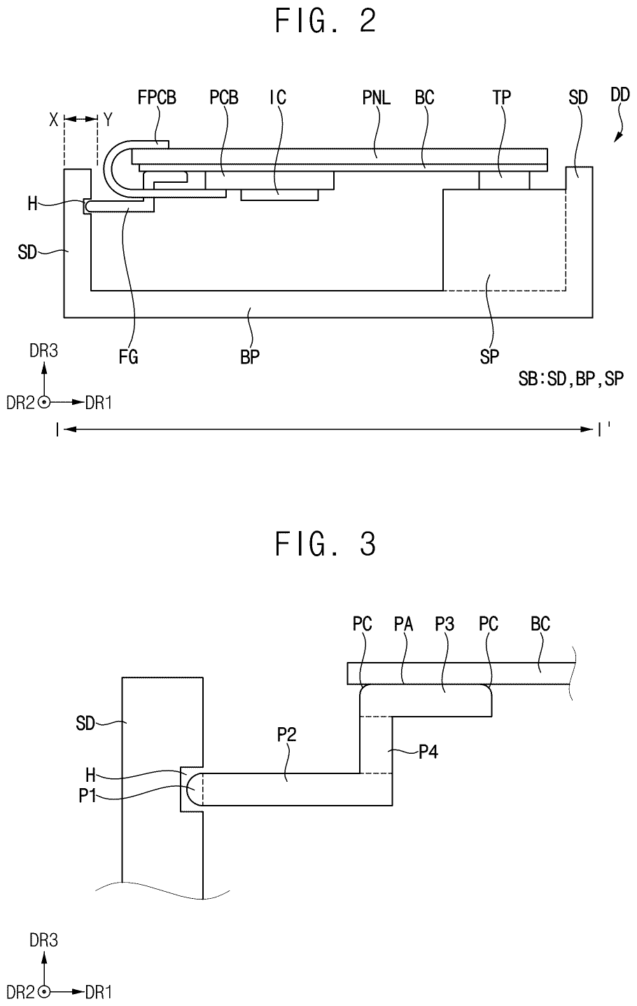

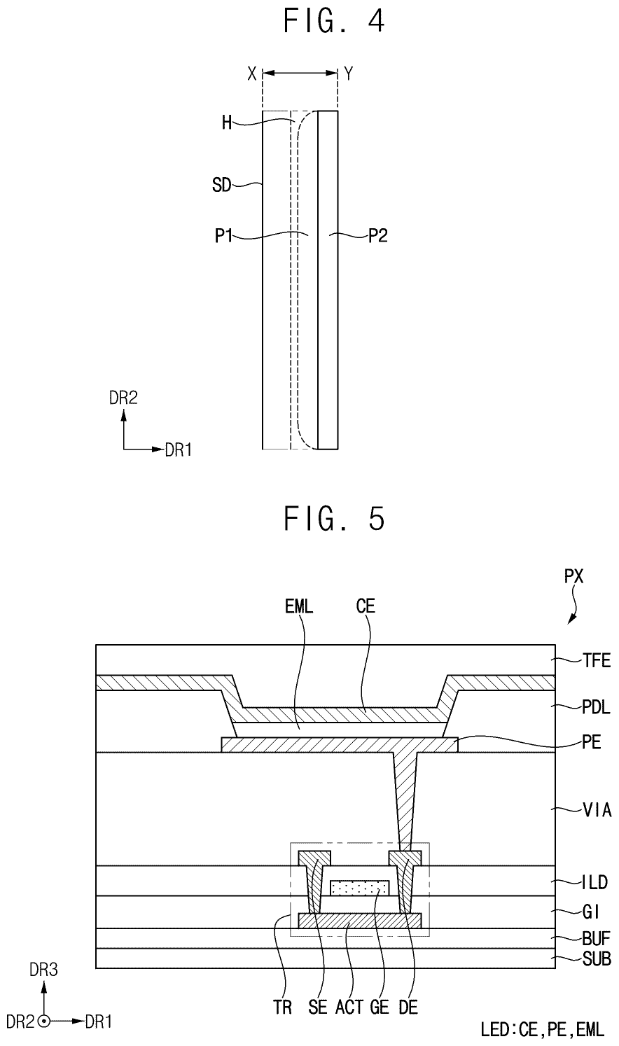

FIG. 2 is a cross-sectional view of the display device of FIG. 1 taken along the line I-I′ of FIG. 1. FIG. 3 is an enlarged cross-sectional view of a flange included in the display device of FIG. 2. FIG. 4 is a plan view illustrating an XY portion of the display device of FIG. 2.

Referring to FIG. 2, the display device DD according to some embodiments may include a display panel PNL, a cover BC, a printed circuit board PCB, a flexible printed circuit board FPCB, a driving chip IC, a set bracket SB, a flange FG, and a tape TP.

The display panel PNL may include a plurality of pixels. For example, the display panel PNL may include a pixel (for example, the pixel PX of FIG. 1). Each of the plurality of pixels may emit light.

According to some embodiments, the cover BC may be located under the display panel PNL. The cover BC may protect a lower surface of the display panel PNL. For example, the cover BC may be located between the display panel PNL and the flange FG, and an impact applied from the flange FG being transferred to the display panel PNL may be prevented or reduced. According to some embodiments, the cover BC may be omitted. In this case, the flange FG, the printed circuit board PCB, and the tape TP may be located under the display panel PNL.

The printed circuit board PCB may be located under the cover BC. For example, the printed circuit board PCB may include a driving board and a plurality of circuit components mounted on the driving board. The printed circuit board PCB may generate and transmit a signal for driving the display panel PNL. For example, the printed circuit board PCB may apply a driving signal, a driving voltage, and the like to the display panel PNL.

The driving chip IC may be located under the printed circuit board PCB. The driving chip IC may partially overlap the printed circuit board PCB in a plan view. The driving chip IC may convert a digital data signal among signals into an analog data signal.

The flexible printed circuit board FPCB may electrically connect the display panel PNL and the printed circuit board PCB. The flexible printed circuit board FPCB may extend along a side surface from a top surface of the display panel PNL. In addition, the flexible printed circuit board FPCB may be fixed on a bottom surface of the printed circuit board PCB. For this, the flexible printed circuit board FPCB may be flexible.

The set bracket SB may be located under the cover BC. The set bracket SB may include a bottom part BP and a side part SD. The side part SD may be connected to the bottom part BP. For example, the side part SD may be connected to an edge of the bottom part BP. In addition, the side part SD may be perpendicular to the bottom part BP.

As the set bracket SB includes a side part SD and a bottom part BP, the set bracket SB may accommodate the cover BC. In addition, the set bracket SB may further accommodate the printed circuit board PCB, the flexible printed circuit board FPCB, the driving chip IC, the tape TP, and the flange FG.

The set bracket SB may further include a supporting part SP. The supporting part SP may be in contact with each of the bottom part BP and the side part SD. For example, the supporting part SP may be a part extending from each of the bottom part BP and the side part SD. According to some embodiments, the supporting part SP may have a rectangular shape in a cross-sectional view.

The cover BC may be attached to the supporting part SP. For example, the cover BC may be attached to the supporting part SP by the tape TP.

According to some embodiments, the side part SD may define a groove H. The groove H may be a portion from which a portion of the side part SD is removed. According to some embodiments, the groove H may have a polygonal shape in cross-sectional view. The groove H may have a rectangular shape in cross-sectional view. However, this disclosure is not limited thereto, and the groove H may have a shape different from the shape of a polygon in cross-sectional view. For example, the groove H may have a semicircular or semi-elliptical shape in cross-sectional view.

Referring further to FIG. 3, the flange FG may be located under the cover BC.

The flange FG may include a first part P1, a second part P2, a third part P3, and a fourth part P4. For example, the flange FG may include metal.

The first part P1 of the flange FG may be accommodated by the groove H. According to some embodiments, the first part P1 may have a convex shape in a direction away from the second part P2 of the flange FG. That is, the first part P1 of the flange FG may have a convex shape in a direction opposite to the first direction DR1. For example, the first part P1 of the flange FG may have a semicircular shape, a semi-elliptical shape, or the like.

Referring further to FIG. 4, the groove H may extend in the second direction DR2. In addition, the first part P1 of the flange FG may be spaced apart from the side part SD of the set bracket SB. That is, the first part P1 of the flange FG may not be in contact with the side part SD of the set bracket SB.

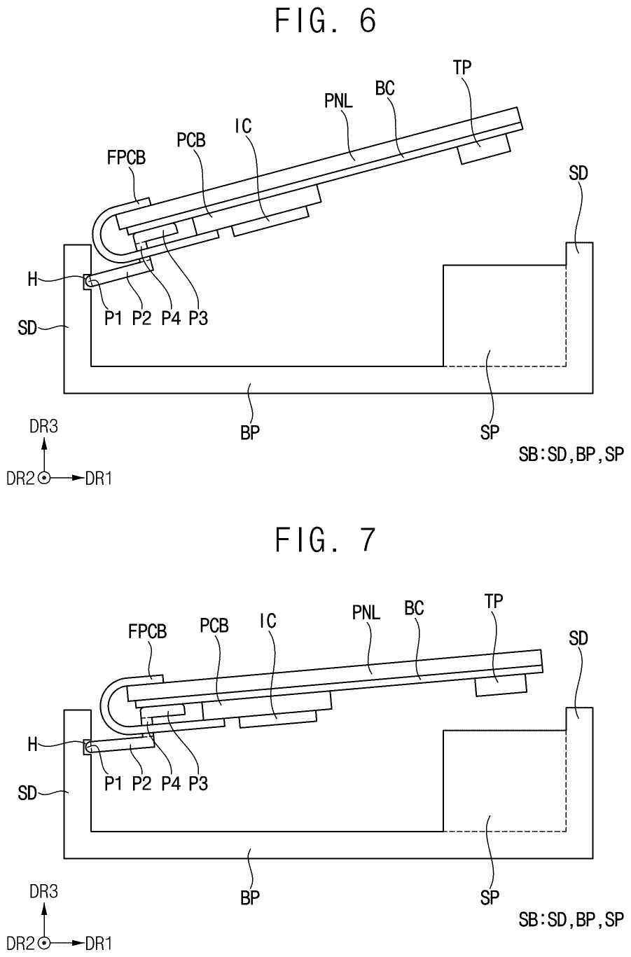

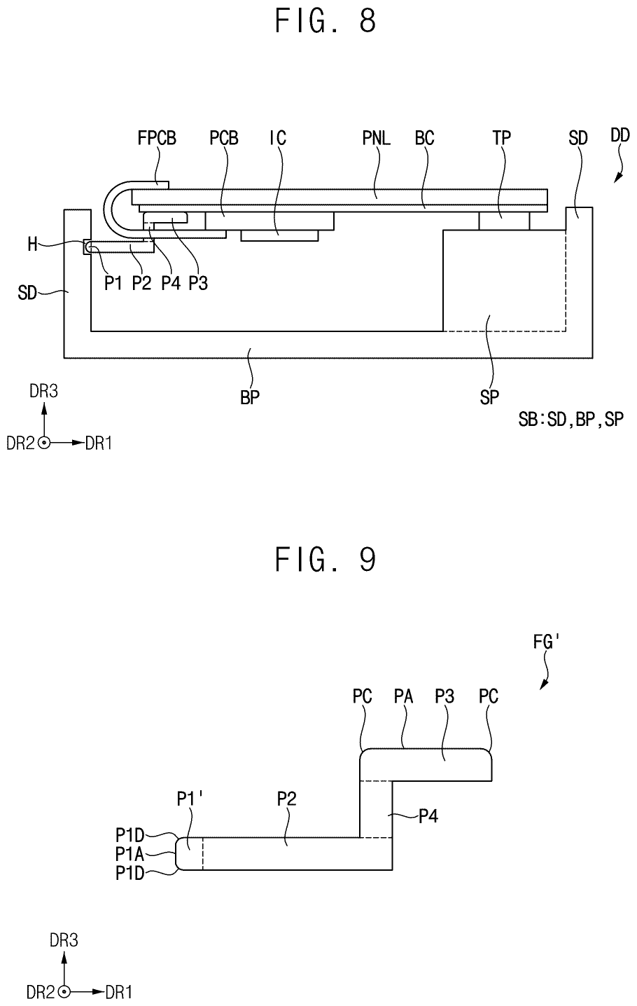

As will be described in more detail later with reference to FIGS. 6, 7, and 8, when the display device DD is manufactured, the flange FG may rotate with the second direction DR2 as an axis. That is, the first part P1 of the flange FG may rotate with the second direction DR2 as an axis. As described above, the first part P1 of the flange FG may have a convex shape. Accordingly, when the first part P1 of the flange FG rotates, the first part P1 of the flange FG may not be in contact with the side part SD of the set bracket SB. Alternatively, when the first part P1 of the flange FG rotates, probability that the first part P1 of the flange FG comes in contact with the side part SD of the set bracket SB may be significantly reduced. Accordingly, an impact may not occur between the first part P1 of the flange FG and the side part SD of the set bracket SB. Accordingly, an impact being transmitted from the first part P1 of the flange FG to the display panel PNL and the cover BC through the flange FG may be prevented or reduced.

The second part P2 of the flange FG may be in contact with the first part P1 of the flange FG. For example, the second part P2 of the flange FG may be in contact with the first part P1 of the flange in the first direction DR1. For example, the second part P2 of the flange FG may have a rectangular shape in cross-sectional view. However, this disclosure is not limited thereto, and the second part P2 of the flange may have a shape different from the rectangular shape in cross-sectional view.

According to some embodiments, the second part P2 of the flange FG may not be accommodated by the groove H. According to some embodiments, the second part P2 of the flange FG may be partially accommodated by the groove H. In this case, the first part P1 of the flange FG and a portion of the second part P2 of the flange FG may be accommodated by the groove H.

Referring back to FIGS. 2 and 3, the third part P3 of the flange FG may be in contact with the cover BC. For example, the third part P3 of the flange FG may include a contact surface PA which is in contact with the cover BC. In addition, the third part P3 of the flange may include a first corner portion PC. The first corner portion PC may be a surface which is in contact with the contact surface PA. For example, the first corner portion PC may be a corner portion of the third part P3 of the flange FG. The corner portion may be adjacent to the cover BC.

According to some embodiments, the first corner portion PC may have a chamfered shape in cross-sectional shape. For example, the first corner portion PC may have a convex shape toward the cover BC. That is, the first corner portion PC may be a curved surface.

According to some embodiments, the first corner portion PC may be spaced apart from the cover BC. That is, the first corner portion PC may not be in contact with the cover BC. That is, as the first corner portion PC has a chamfered shape in cross-sectional view, the first corner portion PC may not be in contact with the cover BC. Accordingly, an impact transferred from the flange FG being applied to the display panel PNL and the cover BC through the first corner portion PC may be prevented or reduced. For example, the impact transferred from the flange FG may be generated when the flange FG rotates during a manufacturing process of the display device DD.

The fourth part P4 of the flange FG may connect the second part P2 of the flange FG and the third part P3 of the flange FG. For example, the fourth part P4 of the flange FG may be connected to one end of the second part P2 of the flange FG. In addition, the fourth part P4 of the flange FG may be connected to one end of the third part P2 of the flange FG. For example, the fourth part P4 of the flange FG may be parallel to the side part SD of the set bracket SB.

FIG. 5 is a cross-sectional view illustrating a pixel included in the display device of FIG. 1.

Referring to FIG. 5, the pixel PX may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

A transistor TR may include the active layer ACT, the source electrode SE, the gate electrode GE, and the drain electrode DE.

The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and the like.

Alternatively, the substrate SUB may include a quartz substrate, a synthetic quartz substrate, a calcium fluoride substrate, a fluorine-doped quartz substrate, a sodalime substrate, a non-alkali glass substrate, or the like. These materials may be used alone or in combination with each other.

The buffer layer BUF may be located on the substrate SUB. The buffer layer BUF may prevent or reduce instances of contaminants, metal atoms, or impurities diffusing from the substrate SUB to the transistor TR. In addition, the buffer layer BUF can improve the flatness of a surface of the substrate SUB when the surface of the substrate SUB is not uniform.

For example, the buffer layer BUF may include an inorganic material such as silicon oxide, silicon nitride, silicon oxynitride, or the like. These materials may be used alone or in combination with each other.

The active layer ACT may be located on the buffer layer BUF. The active layer ACT may include an inorganic semiconductor (e.g., amorphous silicon, polysilicon, a metal oxide semiconductor), an organic semiconductor, and the like. These materials may be used alone or in combination with each other. The active layer ACT may include a source area, a drain area, and a channel area located between the source area and the drain area.

The metal oxide semiconductor may include a binary compound (“ABₓ”), a ternary compound (“ABₓC_{y}”), a tetragonal compound (“ABₓC_{y}D_{z}”), and the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be located on the buffer layer BUF. The gate insulating layer GI may sufficiently cover the active layer ACT, and may have a substantially flat upper surface without generating a step around the active layer ACT. Alternatively, the gate insulating layer GI may cover the active layer ACT and may be arranged along a profile of the active layer ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The gate electrode GE may be located on the gate insulating layer GI. The gate electrode GE may overlap the channel area of the active layer ACT.

The gate electrode GE may include a metal, an alloy metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. In addition, examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be located on the gate insulating layer GI. The interlayer insulating layer ILD may sufficiently cover the gate electrode GE, and may have a substantially flat upper surface without generating a step around the gate electrode GE. Alternatively, the interlayer insulating layer ILD may cover the gate electrode GE, and may be arranged along a profile of the gate electrode GE.

For example, the interlayer insulating layer ILD may include inorganic materials such as silicon oxide, silicon nitride, silicon carbide, silicon oxynitride, silicon oxycarbide, or the like. These materials may be used alone or in combination with each other.

The source electrode SE may be located on the interlayer insulating layer ILD. The source electrode SE may be connected to the source area of the active layer ACT through a contact hole penetrating the gate insulating layer GI and the interlayer insulating layer ILD.

The drain electrode DE may be located on the interlayer insulating layer ILD. The drain electrode DE may be connected to the drain area of the active layer ACT through a contact hole penetrating the gate insulating layer GI and the interlayer insulating layer ILD.

For example, the source electrode SE may include a metal, an alloy, a metal nitride, a conductive metal oxide, a transparent conductive material, and the like. These materials may be used alone or in combination with each other. The drain electrode DE may be formed through the same process as the source electrode SE and may include the same material as the source electrode SE.

The via insulating layer VIA may be located on the interlayer insulating layer ILD. The via insulating layer VIA may sufficiently cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be located on the via insulating layer VIA. The pixel electrode PE may be connected to the drain electrode DE through a contact hole penetrating the via insulating layer VIA.

The pixel electrode PE may include a metal, an alloy, a metal nitride, a conductive metal oxide, a transparent conductive material, or the like. These materials be used alone or in combination with each other. According to some embodiments, the pixel electrode PE may have a stacked structure including ITO/Ag/ITO. For example, the pixel electrode PE may operate as an anode.

The pixel defining layer PDL may be located on the via insulating layer VIA. The pixel defining layer PDL may cover side portions of the pixel electrode PE. In addition, an opening exposing a portion of the upper surface of the pixel electrode PE may be defined in the pixel defining layer PDL.

For example, the pixel defining layer PDL may include an inorganic material or an organic material. According to some embodiments, the pixel defining layer PDL may include an organic material such as an epoxy resin, a siloxane resin, or the like. These materials may be used alone or in combination with each other. According to some embodiments, the pixel defining layer PDL may further include a light blocking material containing a black pigment, a black dye, and the like.

The light emitting layer EML may be located on the pixel electrode PE. The light emitting layer EML may include an organic material that emits light of a color (e.g., a set or predetermined color). For example, the light emitting layer EML may include an organic material that emits red light. However, the present disclosure is not limited thereto, and the light emitting layer EML may emit light of a different color from red light.

The common electrode CE may be located on the light emitting layer EML and the pixel defining layer PDL. The common electrode CE may include a metal, an alloy, a metal nitride, a conductive metal oxide, a transparent conductive material, or the like. These materials may be used alone or in combination with each other. The common electrode CE may operate as a cathode.

A light emitting element LED may include the pixel electrode PE, the light emitting layer EML, and the common electrode.

The encapsulation layer TFE may be located on the common electrode CE. The encapsulation layer TFE may prevent or reduce instances of contaminants, impurities, or moisture penetrating into the pixel electrode PE, the light emitting layer EML, and the common electrode CE from the outside. The encapsulation layer TFE may include at least one inorganic layer and at least one organic layer.

For example, the inorganic layer may include silicon oxide, silicon nitride, silicon oxynitride, and the like. These materials may be used alone or in combination with each other. The organic layer may include a polymer cured product such as polyacrylate.

Although aspects of a pixel PX according to some embodiments have been described with reference to FIG. 5, the pixel PX is not limited to the structure shown in FIG. 5. That is, the pixel PX may include all structures that receive an electrical signal and emit light having a luminance corresponding to the intensity of the electrical signal.

FIGS. 6, 7, and 8 are cross-sectional views illustrating a method of manufacturing the display device of FIG. 2.

Referring to FIG. 6, the display panel PNL, the cover BC, the flange FG, the printed circuit board PCB, the flexible printed circuit board FPCB, the driving chip IC, the tape TP, and the set bracket SB may be formed.

The cover BC may be formed under the display panel PNL. In addition, the printed circuit board PCB may be formed under the cover BC. In addition, the driving chip IC may be formed under the printed circuit board PCB. Also, the flexible printed circuit board FPCB may be formed to electrically connect the display panel PNL and the printed circuit board PCB.

In addition, the flange FG may be formed under the cover BC. The flange FG may include a first part P1, a second part P2, a third part P3, and a fourth part P4. In addition, the set bracket SB may be formed under the cover BC. The set bracket SB may include a bottom part BP and a side part SD. The side part SD of the set bracket SB may define the groove H.

The display panel PNL, the cover BC, the printed circuit board PCB, the flexible printed circuit board FPCB, the driving chip IC, the flange FG, the tape TP, and the set bracket SB may be aligned so that the first part P1 of the flange FG is accommodated by the groove H.

The display panel PNL, the cover BC, the printed circuit board PCB, the flexible printed circuit board FPCB, the driving chip IC, the flange FG, and the tape TP may constitute a first unit. A method of manufacturing the display device (e.g., the display device DD of FIG. 2) according to some embodiments may include a step in which the first unit and the set bracket SB are coupled to each other. FIGS. 6, 7, and 8 may illustrate a step in which the first unit and the set bracket SB are coupled to each other.

Referring to FIG. 7, the first unit may rotate with the second direction DR2 as an axis. When the first unit rotates, the flange FG may support and guide the first unit. That is, the flange FG may support and guide the first unit so that the first unit is well attached to the set bracket SB.

As described above with reference to FIGS. 2, 3, and 4, the first part P1 of the flange FG may have a convex shape. Accordingly, when the first part P1 of the flange FG rotates, the first part P1 of the flange FG may not be in contact with the side part SD of the set bracket SB. Alternatively, when the first part P1 of the flange FG rotates, probability that the first part P1 of the flange FG contacts the side part SD of the set bracket SB may be significantly reduced. Accordingly, an impact may not occur between the first part P1 of the flange FG and the side part SD of the set bracket SB. Accordingly, when the display device is manufactured, transfer of the impact from the first part P1 of the flange FG to the display panel PNL and the cover BC through the flange FG may be prevented or reduced. Even if the first part P1 of the flange FG contacts the side part SD of the set bracket SB, as the first corner portion (e.g., the first corner portion PC of FIG. 3) may have a chamfered shape in a cross-sectional view, the impact transmitted from the flange FG being applied to the display panel PNL and the cover BC through the first corner portion may be prevented or reduced.

FIG. 9 is a cross-sectional view illustrating a flange according to some embodiments. A flange FG′ described with reference to FIG. 9 may be substantially the same as or similar to the flange FG described with reference to FIG. 3 except for a configuration of the first part P1′. Accordingly, redundant descriptions will be omitted or simplified.

Referring to FIG. 9, a flange FG′ according to some embodiments may include a first part P1, a second part P2, a third part P3, and a fourth part P4. The first part P1′ may be accommodated by the groove (for example, the groove H of FIG. 3).

The first part P1′ of the flange FG′ may include a parallel surface P1A and a second corner portion P1D. The parallel surface P1A may be parallel to the side part (e.g., the side portion SD of the set bracket SB of FIG. 3). That is, the parallel surface P1A may be spaced apart from the side part.

According to some embodiments, the second corner portion P1D may have a chamfered shape in cross-sectional view. For example, the second corner portion P1D may have a convex shape in a direction away from the second part P2 of the flange FG′. That is, the second corner portion P1D may be a curved surface. As the second corner portion P1D has a chamfered shape in cross-sectional view, the second corner portion P1D may not be in contact with the side part when the first part P1′ of the flange FG′ rotates. Alternatively, when the first part P1′ of the flange FG′ rotates, probability that the second corner portion P1D comes in contact with the side part may be significantly reduced. Accordingly, an impact being transmitted from the second corner portion P1D to the display panel (e.g., the display panel PNL of FIG. 2) and the cover (e.g., the cover BC of FIG. 2) through the flange FG′ may be prevented or reduced.

Aspects of some embodiments according to the present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a display panel;
a cover under the display panel;
a set bracket accommodating the cover and including a bottom part and a side part connected to the bottom part, wherein the side part of the set bracket defines a groove; and
a flange including:
a first part accommodated by the groove;
a second part contacting the first part; and
a third part including a contact surface contacting the cover and a first corner portion contacting the contact surface, wherein the first corner portion has a chamfered shape in a cross-sectional view.

2. The display device of claim 1, wherein the first part of the flange has a convex shape in a direction away from the second part of the flange.

3. The display device of claim 1, wherein the first part of the flange is spaced apart from the side part of the set bracket.

4. The display device of claim 1, wherein the first corner portion of the third part of the flange is spaced apart from the cover.

5. The display device of claim 1, wherein the first corner portion of the third part of the flange has a convex shape toward the cover.

6. The display device of claim 1, wherein the flange further includes:
a fourth part connecting the second part of the flange and the third part of the flange.

7. The display device of claim 6, wherein the fourth part is parallel to the side part of the set bracket.

8. The display device of claim 1, wherein the first part of the flange includes:
a parallel plane which is parallel to the side part of the set bracket; and
a second corner portion adjacent to the parallel plane.

9. The display device of claim 8, wherein the second corner portion of the first part of the flange has a chamfered shape in a cross-sectional view.

10. The display device of claim 9, wherein the second corner portion of the first part of the flange has a convex shape in a direction way from the second part of the flange.

11. The display device of claim 1, wherein the set bracket further includes:
a supporting part contacting each of the bottom part of the set bracket and the side part of the set bracket.

12. The display device of claim 11, wherein the cover is attached to the supporting part by tape.

13. The display device of claim 1, wherein the side part of the set bracket is connected to an edge of the bottom part of the set bracket.

14. The display device of claim 1, wherein the flange includes metal.

15. A method of manufacturing a display device, comprising:
forming a display panel;
forming a cover under the display panel;
forming a flange including a first part, a second part contacting the first part, and
a third part including a contact surface contacting the cover and a first corner portion contacting the contact surface, wherein the first corner portion has a chamfered shape in a cross-sectional view;
forming a set bracket accommodating the cover and including a bottom part and a side part connected to the bottom part, wherein the side part of the set bracket defines a groove;
aligning the display panel, the cover, the flange, and the set bracket so that the first part of the flange is accommodated in the groove of the side part of the set bracket; and
rotating the display panel, the cover, and the flange so that the cover is attached to the set bracket.

16. The method of claim 15, wherein the first part of the flange has a convex shape in a direction away from the second part of the flange.

17. The method of claim 16, wherein the groove of the side part of the set bracket extends in one direction,
the rotating the display panel, the cover, and the flange includes rotating the display panel, the cover, and the flange with the one direction as an axis.

18. The method of claim 15, wherein the first part of the flange is spaced apart from the side part of the set bracket.

19. The method of claim 15, wherein the first corner portion of the third part of the flange is spaced apart from the cover.

20. The method of claim 15, wherein the first corner portion of the third part of the flange has a convex shape toward the cover.
